(19) United States
(12) Patent Application Publication
(10) Pub. No.: US 2006/0027920 A1
(43) Pub. Date: Feb. 9, 2006

(54) Electronic component production method and electronic component produced by the method

(75) Inventor: Tomohide Aramata, Nagaokakyo-shi (JP)

Correspondence Address: OSTROLENK FABER GERB & SOFFEN, 1180 AVENUE OF THE AMERICAS, NEW YORK, NY, 100368403, US

(73) Assignee: Murata Manufacturing Co., Ltd.

(21) Appl. No.: 11/125,365

(22) Filed: May 9, 2005

(30) Foreign Application Priority Data
Aug. 6, 2004 (JP) 2004-230077

(51) Int. Cl. H01L 29/76

(52) U.S. Cl. 257/735

(57) ABSTRACT

A method for adjusting the characteristics of individual substrates by trimming, while a plurality of the individual substrates are coupled to each other to constitute a parent substrate. One measurement probe is made to contact an adjacent terminal electrode of an adjacent individual substrate that is connected to a terminal electrode of an individual substrate to be trimmed with an inner electrode therebetween. The other measurement probe is made to contact either an adjacent terminal electrode of another adjacent individual substrate that is connected to another terminal electrode of the individual substrate to be trimmed with an inner electrode therebetween, or another terminal electrode of the individual substrate to be trimmed. An adjustment electrode of the individual substrate to be trimmed is laser-trimmed while the probes are in contact.

### BACKGROUND OF THE INVENTION

1. Field of the Invention

The present invention relates to electronic components having a land grid array (LGA) terminal structure and methods for producing the electronic components.

2. Description of the Related Art

A surface-mount multifunction electronic component including a substrate and a surface-mounted component, and having an LGA terminal structure, is suggested in Japanese Unexamined Patent Application Publication No. 2002-217351. The substrate includes a terminal electrode including a two-dimensional thick-film electrode on a rear or bottom surface of the substrate. The surface-mounted component is mounted on the substrate and connected to the terminal electrode with a through hole and the thick-film electrode therebetween.

In order to implement mass production, electronic components of this type are produced by forming terminal electrodes and mounting surface-mounted components on a parent-substrate, and then dividing the parent substrate into individual substrates. In some cases, however, it is desirable to measure and adjust the characteristics of each individual substrate before the parent substrate is divided into the individual substrates.

A method for adjusting a voltage-controlled oscillator using a microstrip line resonator is disclosed in Japanese Unexamined Patent Application Publication No. 2001-292028. The voltage-controlled oscillator includes a strip electrode provided on one face of a dielectric substrate, a case provided on the one face of the dielectric substrate so as to cover the strip electrode, and a ground electrode provided on the other face of the dielectric substrate. In this adjusting method, characteristics, such as frequency, are adjusted by trimming the strip electrode using a laser beam from the other face of the dielectric substrate after the case is formed.

In order to adjust such characteristics, probes, for example, for applying a supply voltage, for a ground, for signal input, and for signal output must be made to contact the terminal electrodes. However, it is difficult to adjust such characteristics in the parent-substrate. Since each probe because of its size covers most of the rear face of each individual substrate, it is difficult to irradiate a necessary area with a laser beam.

FIG. 6 illustrates a method for irradiating a stripline electrode 54, which is an adjustment electrode, with a laser beam 53 from the same direction as probes 52 while the probes 52 are made to contact terminal electrodes 51 of a parent substrate 50. Reference numerals 55 and 56 denote ground electrodes, reference numeral 57 denotes a surface-mounted component, and reference numeral 58 denotes a division line to cut the parent substrate 50 into individual substrates.

As is clear from FIG. 6, since interference may occur between the probes 52 and the laser beam 53, only a restricted area can be irradiated with the laser beam 53. Thus, it is difficult to perform an adjusting operation. In addition, since the stripline electrode 54 must be arranged in a vacant area, the design flexibility is reduced.

### SUMMARY OF THE INVENTION

Accordingly, the present invention provides a method for producing an electronic component in which an area of an individual substrate blocked by a probe is reduced, an adjusting operation can be performed easily, and the flexibility in locating an adjustment electrode is increased, and an electronic component produced by such a method.

According to an aspect of the present invention, an electronic component production method includes the steps of preparing a parent substrate in a state in which a plurality of individual substrates are coupled to each other, the parent substrate including a plurality of terminal electrodes provided, for each of the individual substrates independently, on a bottom surface of the parent substrate; inner electrodes disposed on an inner layer of the parent substrate, the inner electrodes connecting the terminal electrodes of each of the individual substrates to adjacent terminal electrodes of an adjacent individual substrate; and an adjustment electrode provided in each of the individual substrates independently; causing, in order to measure a characteristic of a particular individual substrate, one measurement probe to contact an adjacent terminal electrode of an adjacent individual substrate that is connected to a terminal electrode of the particular individual substrate with the corresponding inner electrode therebetween and causing the other measurement probe to contact either another terminal electrode of the particular individual substrate or an adjacent terminal electrode of another adjacent individual substrate that is connected to the other terminal electrode of the particular individual substrate with the corresponding inner electrode therebetween; trimming the adjustment electrode of the particular individual substrate while the probes are in contact; and dividing the trimmed parent substrate into the individual substrates.

According to another aspect of the present invention, an electronic component includes a substrate; a plurality of terminal electrodes disposed on a bottom surface of the substrate and along a periphery of the substrate; an adjustment electrode to be trimmed disposed approximately between the terminal electrodes, for example at the center of the substrate; and inner electrodes electrically connected to the terminal electrodes, a cross section of each of the inner electrodes being exposed at a side face of the substrate along which the terminal electrodes are disposed.

A terminal electrode of each of a plurality of individual substrates that are coupled to each other (forming a parent substrate), and an adjacent terminal electrode of an adjacent individual substrate, are connected to each other with an inner electrode of the parent substrate therebetween. The inner electrode is not exposed at the top or bottom surface of the substrate. The terminal electrode is connected to the inner electrode by, for example, a through hole therebetween. In contrast, an adjustment electrode is formed in advance on the top or bottom surface of the parent substrate or on an inner layer of the parent substrate.

Then, a measurement probe is made to contact an adjacent terminal electrode of an adjacent individual substrate, instead of a terminal electrode of an individual substrate to be trimmed. Since the adjacent terminal electrode that contacts the probe is connected to the terminal electrode of the individual substrate to be trimmed with the inner electrode therebetween, the electric characteristics of the individual substrate to be trimmed can be measured using the adjacent terminal electrode of the adjacent individual substrate. Thus, since an area of the bottom surface of the individual substrate to be trimmed that is blocked by the probe is reduced, interference between a laser beam and the probe is unlikely to occur when the adjustment electrode is trimmed using the laser beam. Thus, the flexibility in arranging the adjustment electrode can be increased.

The adjustment electrode is not necessarily provided on the top or bottom surface of the parent substrate. The adjustment electrode may instead be provided on an inner layer of the parent substrate.

Even if the adjustment electrode is disposed on an inner layer of the substrate, the laser beam reaches the adjustment electrode inside the substrate. Thus, the adjustment electrode can be trimmed.

When the parent substrate is divided into individual substrates by dicing or the like, the inner electrode used for connecting the terminal electrodes is divided. However, since the inner electrode is provided on an inner layer inside each of the individual substrates and is not provided on the top surface of the substrate, electrode exfoliation or burr occurring at the dicing cut can be suppressed or prevented.

A probe is not necessarily an adjacent terminal electrode of an adjacent individual substrate that is adjacent to an individual substrate to be trimmed. One probe may be made to contact an adjacent terminal electrode of an adjacent individual substrate, and the other probe may be made to contact a terminal electrode of the individual substrate to be trimmed. In other words, by causing at least one probe to contact an adjacent terminal electrode of an adjacent individual substrate, interference between a laser beam and the probe can be prevented.

Preferably, the terminal electrodes are arranged along a periphery of each of the individual substrates. In addition, preferably, the adjustment electrode is provided between the terminal electrodes, for example at approximately the center of each of the individual substrates.

By arranging the terminal electrodes along the periphery of each individual substrate, the inner electrode used for connection with the terminal electrode of the adjacent individual substrate can be simplified. Thus, the reliability of the connections can be increased.

Since a space is generated at the center of the individual substrate by providing the terminal electrodes at the periphery of the individual substrate, the adjustment electrode can be located easily.

Preferably, margins that are not used as the individual substrates are provided at a periphery of the parent substrate. In addition, preferably, dummy terminal electrodes that are connected to adjacent terminal electrodes of corresponding adjacent individual substrates with corresponding inner electrodes therebetween are provided in the margins.

For an individual substrate located at approximately the center of the parent substrate, since adjacent individual substrates exist, probes can be made to contact adjacent terminal electrodes of the adjacent individual substrates, as described above. In contrast, for an individual substrate located at the periphery of the parent substrate, an adjacent individual substrate exists only at one side. In order to deal with this case, a margin is formed at the periphery of the parent substrate, and a dummy terminal electrode formed in the margin is connected to the adjacent terminal electrode of the adjacent individual substrate with the inner electrode therebetween.

In other words, instead of contacting a terminal electrode of an individual substrate, the dummy terminal electrode provided at the margin is made to contact a probe so that characteristics can be measured. In this case, similarly, an interference between the laser beam and the probe can be prevented.

In an electronic component according to an aspect of the present invention, a plurality of terminal electrodes are disposed on a bottom surface of a substrate and along a periphery of the substrate, an adjustment electrode to be trimmed is disposed at approximately the center of the substrate, and inner electrodes electrically connected to the terminal electrodes are arranged such that a cross section of each of the inner electrodes is exposed at a side face of the substrate along which the terminal electrodes are disposed. Thus, an electronic component that has an increased flexibility in arranging the adjustment electrode and that can be adjusted with high accuracy can be achieved.

Accordingly, a terminal electrode of each of the individual substrates while still conencted in the parent-substrate state is connected to an adjacent terminal electrode of an adjacent individual substrate with an inner electrode therebetween. An adjustment electrode of an individual substrate to be trimmed is trimmed while the characteristics of the individual substrate to be trimmed are measured by causing a measurement probe to contact the adjacent terminal electrode of the adjacent individual substrate, instead of the terminal electrode of the individual substrate to be trimmed. Thus, an area of a bottom surface of the individual substrate to be trimmed that is covered by the probe is reduced, and interference between the trimming element and the probe is unlikely to occur. Thus, an adjusting operation can be performed easily, and flexibility in arranging the adjustment electrode can be increased.

Other features and advantages of the present invention will become apparent from the following description of the invention which refers to the accompanying drawings.

### BRIEF DESCRIPTION OF THE DRAWINGS

FIG. 1 is a cross-sectional view of an electronic component according to a first embodiment of the present invention;

FIG. 2 is a bottom view of the electronic component shown in FIG. 1;

FIG. 3 is a cross-sectional view of a parent substrate including many electronic components shown in FIG. 1 that are coupled to each other;

FIG. 4 is a bottom view of the parent substrate shown in FIG. 3;

FIG. 5 is a cross-sectional view of a parent substrate according to a second embodiment of the present invention for explaining an electronic component adjusting method; and

FIG. 6 is a cross-sectional view of a parent substrate for explaining a known electronic component adjusting method.

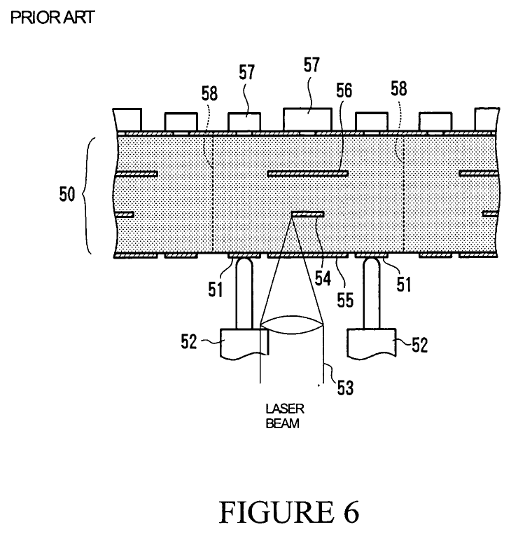

### DESCRIPTION OF EMBODIMENTS OF THE INVENTION

Embodiments of the present invention will be described with reference to the drawings.

### First Embodiment

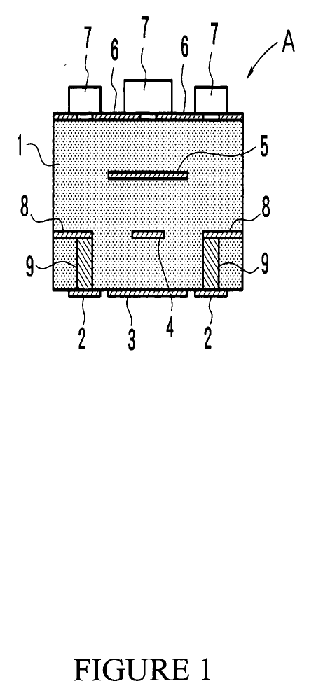

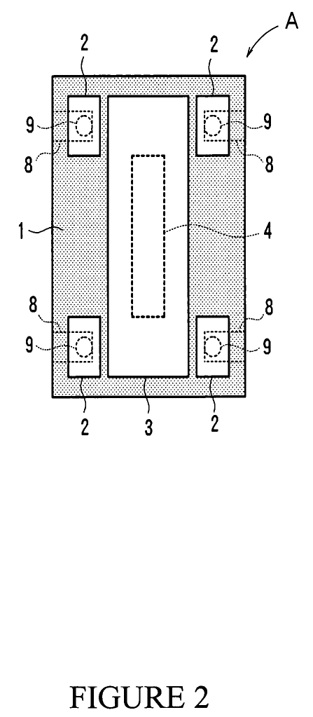

FIGS. 1 and 2 show a high-frequency module having a multilayer structure. This high-frequency module is an example of an electronic component having an LGA terminal structure. Here, an example of a high-frequency voltage-controlled oscillator (VCO) module A is described.

The VCO module A includes a substrate 1 formed by a plurality of laminated dielectric layers. The dielectric layers may be made of resin or ceramics. Four terminal electrodes 2 and a ground electrode 3 are disposed on the rear surface of the substrate 1. The terminal electrodes 2 are arranged along a periphery of the substrate 1. The ground electrode 3 is arranged at approximately the center of the rear surface of the substrate 1.

A stripline electrode (adjustment electrode) 4 is disposed in a region inside the substrate 1 that is above the ground electrode 3. A ground electrode 5 is disposed in a region inside the substrate 1 that is above the stripline electrode 4. The area of the stripline electrode 4 is smaller than the respective areas of the ground electrode 3 and the ground electrode 5. The ground electrode 3, the stripline electrode 4, and the ground electrode 5 constitute a stripline resonator having a triplate structure. Circuit electrodes 6 are disposed on the top surface of the substrate 1. A plurality of elements 7, such as a transistor and a capacitor, are mounted on the circuit electrodes 6. The circuit electrodes 6, the stripline electrode 4, and the ground electrode 5 are connected to each other with via conductors (though holes) or end face electrodes, which are not shown, therebetween.

Inner electrodes 8 are disposed in regions inside the substrate 1 that correspond to the terminal electrodes 2. The terminal electrodes 2 and the corresponding inner electrodes 8 are connected to each other with via conductors 9 therebetween. A cross section of one end of each of the inner electrodes 8 is exposed at a side face of the substrate 1. The terminal electrodes 2 are connected to the circuit electrodes 6, which are disposed on the top surface of the substrate 1, and the stripline electrode 4 and the ground electrode 5, which are disposed inside the substrate 1, with via conductors (not shown) therebetween.

Although an example using four terminal electrodes in the VCO module A is shown in FIG. 2, it is obvious that more than four terminal electrodes may be used.

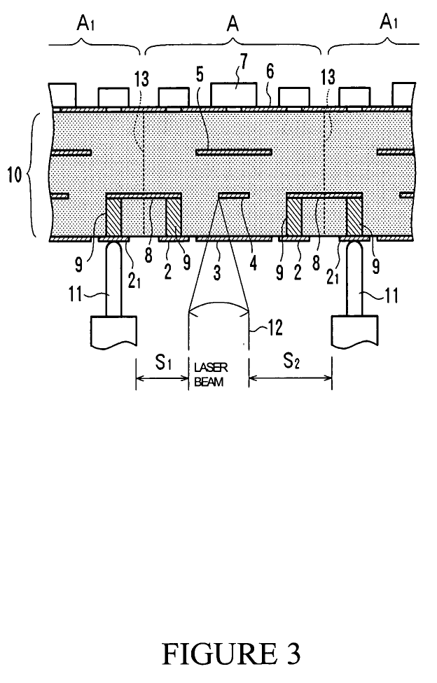

FIG. 3 shows a parent substrate 10 for producing the VCO module A. The parent substrate 10 includes a plurality of coupled individual substrates (VCO modules A), which will be divided later.

The parent substrate 10 including the terminal electrodes 2, the ground electrodes 3 and 5, the stripline electrode 4, the circuit electrodes 6, the inner electrodes 8, and the like, is prepared in advance, and the elements 7 are mounted on the circuit electrodes 6.

Then, the stripline electrode 4 is irradiated with a laser beam 12 to adjust the frequency of the voltage-controlled oscillator while probes 11 for measuring electric characteristics are electrically connected to the terminal electrodes 2 of the VCO module A to be trimmed. In order to prevent interference between the probes 11 and the laser beam 12, instead of contacting the terminal electrodes 2 of the VCO module A to be trimmed, the probes 11 are made to contact the adjacent terminal electrodes 2₁ of the two adjacent VCO modules A₁. Since the terminal electrodes 2 of the VCO module A to be trimmed and the adjacent terminal electrodes 2₁ of the adjacent VCO modules A₁ are connected to each other with the inner electrodes 8 and the via conductors 9 therebetween, there is no need to cause the probes 11 to contact the terminal electrodes 2 of the VCO module A to be trimmed.

Although an example using two probes is described here, three or more probes, for example, for applying a supply voltage, for a ground, for signal input, or for signal output may be in contact at the same time.

Accordingly, spaces S₁ and S₂ between the laser beam 12 and the probes 11 can be achieved. Thus, an area that can be trimmed using the laser beam 12 is increased, and the stripline electrode 4 can be easily trimmed with high accuracy. Furthermore, since the area of the bottom surface of the VCO module A that is blocked by the probes 11 is reduced, the region in which the stripline electrode 4 is formed can be set relatively flexibly. Thus, flexibility in designing the module is increased.

After adjusting the frequency, the parent substrate 10 is diced, along division lines 13 represented by the broken lines in FIG. 3, to be divided into the individual substrates (the VCO modules A). In the process of division, the inner electrodes 8 are also divided. Since the inner electrodes 8 are disposed inside the parent substrate 10, electrode exfoliation or burr occurring at a dicing cut can be prevented.

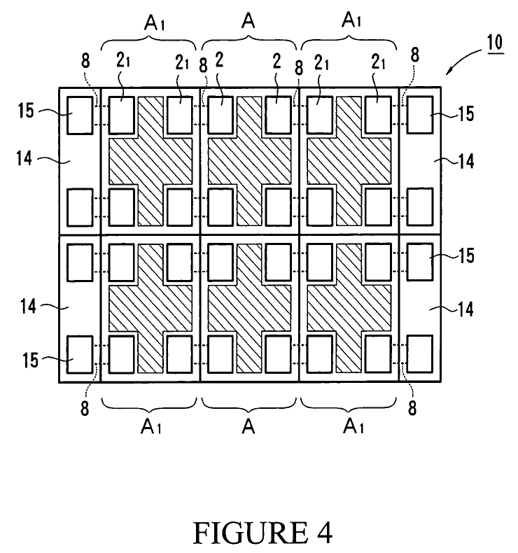

FIG. 4 shows the bottom surface of the parent substrate 10.

As shown in FIG. 4, margins 14 are provided at the periphery of the parent substrate 10. Dummy terminal electrodes 15 are disposed in the margins 14. Each of the dummy terminal electrodes 15 is connected to the adjacent terminal electrode 2₁ of the adjacent individual substrate (adjacent VCO module A₁) with the inner electrode 8 therebetween.

For an individual substrate (VCO module A) located at approximately the center of the parent substrate 10, since the adjacent individual substrates (adjacent VCO modules A₁) exist as described above, the probes 11 can be made to contact the adjacent terminal electrodes 2₁ of the adjacent individual substrates (adjacent VCO modules A₁). In contrast, for an adjacent individual substrate (VCO module A₁) located at the periphery of the parent substrate 10, an adjacent individual substrate exists at only one side. In this case, the probe 11 near the periphery of the parent substrate 10 can be made to contact the adjacent terminal electrode 2₁ using the dummy terminal electrode 15 in the margin 14 that is adjacent to the adjacent individual substrate (adjacent VCO module A₁).

The shaded areas in FIG. 4 represent areas in which the stripline electrodes 4 can be formed. As described above, by causing the probe 11 to contact the terminal electrode 2 using the adjacent terminal electrode 2₁ of the adjacent individual substrate (adjacent VCO module A₁) and by causing the probe 11 to contact the adjacent terminal electrode 21 using the dummy terminal electrode 15 in the margin 14 provided at the periphery of the parent substrate 10, the areas in which the stripline electrode 4 can be formed is increased.

### Second Embodiment

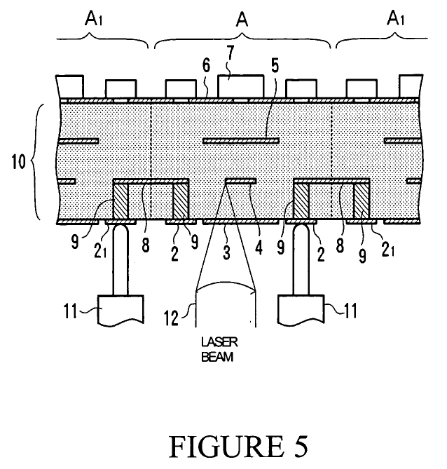

FIG. 5 shows a method of characteristics measurement and trimming according to a second embodiment of the present invention.

In the second embodiment, one of the probes 11 is made to contact the adjacent terminal electrode 2₁ of the adjacent individual substrate (adjacent VCO module A₁) and the other one of the probes 11 is made to contact the terminal electrode 2 of the individual substrate (VCO module A) to be trimmed, instead of both of the probes 11 contacting the adjacent terminal electrodes 21 of the adjacent VCO modules A₁.

Especially when the position of the laser beam 12, in other words, the position of the stripline electrode 4 to be trimmed, deviates toward one of the terminal electrodes 2 of the individual substrate (VCO module A), it is not necessary for both the probes 11 to contact the adjacent terminal electrodes 21 of the adjacent VCO modules A₁. Instead the probe 11 may be made to contact the other one of the terminal electrodes 2 of the individual substrate (VCO module A), and even in that case, interference between the laser beam 12 and the probe 11 is still reduced.

The present invention is not limited to the foregoing embodiments. Various changes and modifications can be made to the present invention without departing from the spirit and scope of the present invention.

Although an example has been described in which a VCO module including a multilayer substrate having a plurality of laminated dielectric layers is used as an electronic component, the electronic component may also include a substrate having a single-layer structure. Thus, the present invention is also applicable to other electronic components having an LGA terminal structure, such as a hybrid integrated circuit (IC), an active filter, and a DC/DC converter.

Although the electrode that functions as an adjustment electrode in the foregoing embodiments is a stripline, it is obvious that the adjustment electrode is not necessarily limited to being a stripline electrode. In addition, the adjustment electrode is not necessarily disposed inside the substrate. The adjustment electrode may be exposed on the top or bottom surface or another surface of the substrate.

In addition, the invention is not limited to laser trimming. It is obvious that another known trimming method, such as sandblasting, may be adopted.

Although the present invention has been described in relation to particular embodiments thereof, many other variations and modifications and other uses will become apparent to those skilled in the art. Therefore, the present invention is not limited by the specific disclosure herein.

What is claimed is:

1. An electronic component production method comprising the steps of:
preparing a parent substrate comprising a plurality of individual substrates coupled to each other, the parent substrate including: a plurality of respective terminal electrodes for each of the individual substrates, on a surface of the parent substrate; inner electrodes disposed within the parent substrate, the inner electrodes connecting the terminal electrodes of each of the individual substrates to adjacent terminal electrodes of a respective adjacent individual substrate; and an adjustment electrode provided in each of the individual substrates;
measuring a characteristic of a particular individual substrate, by contacting with a measurement probe an adjacent terminal electrode of an adjacent individual substrate that is connected to a terminal electrode of the particular individual substrate by the corresponding inner electrode therebetween, and contacting with another measurement probe either another terminal electrode of the particular individual substrate or an adjacent terminal electrode of another adjacent individual substrate that is connected to the other terminal electrode of the particular individual substrate with the corresponding inner electrode therebetween;
trimming the adjustment electrode of the particular individual substrate while the probes are in contact; and
dividing the parent substrate to separate the individual substrates.

2. The electronic component production method according to claim 1, wherein:
the terminal electrodes are arranged along a periphery of each of the individual substrates; and
the adjustment electrode is located between the terminal electrodes.

3. The electronic component production method according to claim 2, wherein the adjustment electrode is located at approximately the center of each of the individual substrates.

4. The electronic component production method according to claim 2, wherein the parent substrate further includes:
margins at a periphery of the parent substrate; and
dummy terminal electrodes in the margins that are connected to adjacent terminal electrodes of corresponding adjacent individual substrates with corresponding inner electrodes therebetween.

5. The electronic component production method according to claim 1, wherein the parent substrate further includes:
margins at a periphery of the parent substrate; and
dummy terminal electrodes in the margins that are connected to adjacent terminal electrodes of corresponding adjacent individual substrates with corresponding inner electrodes therebetween.

6. An electronic component comprising:
a substrate;
a plurality of terminal electrodes disposed on a surface of the substrate and along a periphery of the substrate;
an adjustment electrode disposed between the terminal electrodes; and
inner electrodes electrically connected to the terminal electrodes, a cross section of each of the inner electrodes being exposed at a side face of the substrate along which the terminal electrodes are disposed.

7. The electronic component production method according to claim 6, wherein said adjustment electrode is disposed at approximately the center of the substrate.

8. A parent substrate for use in producing a plurality of separate individual substrates, comprising:
a plurality of individual substrates coupled to each other; a plurality of respective terminal electrodes for each of the individual substrates, on a surface of the parent substrate; inner electrodes disposed within the parent substrate, the inner electrodes connecting the terminal electrodes of each of the individual substrates to adjacent terminal electrodes of a respective adjacent individual substrate; and an adjustment electrode provided in each of the individual substrates;
said parent substrate being divisible to form said plurality of separate individual substrates, each said separate individual substrate thereby comprising:
a plurality of terminal electrodes disposed on a surface of the substrate and along a periphery of the substrate;
an adjustment electrode disposed between the terminal electrodes; and
inner electrodes electrically connected to the terminal electrodes, a cross section of each of the inner electrodes being exposed at a side face of the substrate along which the terminal electrodes are disposed.

9. A parent substrate for use in producing a plurality of individual substrates according to claim 8, wherein said adjustment electrode is disposed at approximately the center of the respective individual substrate.

10. A parent substrate for use in producing a plurality of individual substrates according to claim 8, wherein the parent substrate further includes:
margins at a periphery of the parent substrate; and
dummy terminal electrodes in the margins that are connected to adjacent terminal electrodes of corresponding adjacent individual substrates with corresponding inner electrodes therebetween.
